(19) United States
(12) Patent Application Publication
(10) Pub. No.: US 2016/0163643 A1
(43) Pub. Date: Jun. 9, 2016

(54) E-FUSE DEVICES AND METHOD FOR FABRICATING THE SAME

(71) Applicant: Samsung Electronics Co., Ltd., Suwon-si (KR)

(72) Inventors: Hyun-Min CHOI, Uiwang-si (KR); Chul-Yong Park, Hwaseong-si (KR)

(21) Appl. No.: 14/955,554

(22) Filed: Dec. 1, 2015

(30) Foreign Application Priority Data
Dec. 5, 2014 (KR) 10-2014-0173613

(51) Int. Cl. H01L 23/525

(52) U.S. Cl. CPC H01L 23/5256

(57) ABSTRACT

E-fuse devices, and a method of manufacturing the same, include a first metal pattern extending in a first direction to connect a first electrode and a second electrode to each other, a first barrier metal contacting lateral surfaces and a bottom surface of the first metal pattern, and a first capping insulation layer contacting a top surface of the first metal pattern, wherein the first metal pattern includes an exposed region, the first barrier metal or the first capping insulation layer not contacting a top surface or a bottom surface of the exposed region.

### CROSS-REFERENCE TO RELATED APPLICATION

This application claims priority from Korean Patent Application No. 10-2014-0173613 filed on Dec. 5, 2014 in the Korean Intellectual Property Office, and all the benefits accruing therefrom under 35 U.S.C. 119, the contents of which in their entirety are herein incorporated by reference.

### BACKGROUND

1. Field

Example embodiments of the present inventive concepts relate to e-fuse devices and/or a method for manufacturing the same.

2. Description of the Related Art

In e-fuse fields, e-fuse structures are used for various purposes. For example, in order to improve the yield of chips of a memory device, an e-fuse structure may be used in a repair process for replacing a defective memory cell with a redundant memory cell. In addition to the repair process, after chip identification for recording information about fabrication histories of e-fuse chips or fab-out, the e-fuse structure may also be used for chip customization to improve and/or optimize characteristics of fabricated e-fuse chips.

Fuses may be classified as either laser fuses or e-fuses. Laser fuses are configured to be selectively programmed (that is, opened) by utilization of a laser, and e-fuses are configured to be selectively programmed by utilization of electric current.

### SUMMARY

Example embodiments of the present inventive concepts relate to e-fuse devices and/or a method for manufacturing the same.

Example embodiments of the present inventive concepts provide an e-fuse device having improved fusing performance so as to be programmable at a low voltage.

Example embodiments of the present inventive concepts also provide a method for manufacturing an e-fuse device having improved fusing performance so as to be programmable at a low voltage.

These and other example embodiments of the present inventive concepts will be described in or be apparent from the following description of the preferred embodiments.

According to example embodiments of the present inventive concepts, there is provided an e-fuse device including a first metal pattern extending in a first direction to connect a first electrode and a second electrode to each other, a first barrier metal contacting with lateral surfaces and a bottom surface of the first metal pattern, and a first capping insulation layer contacting a top surface of the first metal pattern, the first metal pattern including an exposed region, the first barrier metal or the first capping insulation layer not contacting a top surface or a bottom surface of the exposed region.

In example embodiments of the present inventive concepts, the e-fuse device may further comprise a first interlayer insulation layer on the first capping insulation layer, the exposed region being on the top surface of the first metal pattern, and contacting the first interlayer insulation layer.

In example embodiments of the present inventive concepts, the first interlayer insulation layer includes a low-k dielectric.

In example embodiments of the present inventive concepts, the exposed region is on the top surface of the first metal pattern, and the first capping insulation layer and the exposed region define a cavity filled with air therebetween.

In example embodiments of the present inventive concepts, a top surface of the exposed region is lower than a top surface of the first metal pattern other than the exposed region.

In example embodiments of the present inventive concepts, exposed region is on the top surface of the first metal, and the e-fuse device further comprises a first interlayer insulation layer on the first capping insulation layer, a second capping insulation layer on the interlayer insulation layer, the exposed region and the second capping insulation layer defining a cavity filled with air therebetween.

In example embodiments of the present inventive concepts, a top surface of the exposed region is equal to, or higher than a top surface of the first metal pattern other than the exposed region.

In example embodiments of the present inventive concepts, the first and second capping insulation layers are not in contact with each other.

In example embodiments of the present inventive concepts, sidewalls of the cavity include the second capping insulation layer and the first interlayer insulation layer.

In example embodiments of the present inventive concepts, the first metal pattern and the air gap are formed in the first region, and the e-fuse device further comprises a second metal pattern in the second region to be spaced apart from the first metal pattern and the first capping insulation layer and a via pattern extending through the first capping pattern and the first interlayer insulation layer, a top surface of the via pattern contacting the second capping insulation layer.

In example embodiments of the present inventive concepts, the via pattern includes a second barrier metal conformally along sidewalls and a bottom surface of the via pattern.

In some example embodiments of the present inventive concepts, the exposed region is on a bottom surface of the first metal pattern, and the e-fuse device further comprises a second interlayer insulation layer contacting a bottom surface of the first barrier metal, and a cavity filled with air between the second interlayer insulation layer and the first metal pattern.

According to example embodiments of the present inventive concepts, there is provided an e-fuse device including an interlayer insulation layer on a first etch stop layer, a metal pattern filling a recess, the recess being in the interlayer insulation layer, and the metal pattern extending in a first direction, and a capping insulation layer covering the metal pattern and the interlayer insulation layer, lateral surfaces of the metal pattern and a bottom surface of the capping insulation layer defining a cavity filled with air, the cavity extending in the first direction, and wherein the cavity is not in contact with the metal pattern.

In example embodiments of the present inventive concepts, the first etch stop layer and the interlayer insulation layer have an etching selectivity with respect to each other.

In example embodiments of the present inventive concepts, the e-fuse device may further comprise a barrier metal covering an entirety of a bottom surface and lateral surfaces of the metal pattern in the first direction, the cavity contacting the capping insulation layer, the interlayer insulation layer and the barrier metal.

According to example embodiments, an e-fuse device includes a metal pattern electrically connecting a first electrode and a second electrode, a barrier metal under the metal pattern, and a capping insulation layer over the barrier metal, the metal pattern having a region exposed by the capping insulation layer. The metal pattern and at least one selected from the barrier metal and the capping insulation layer define a cavity filled with air.

At least a surface of the metal pattern may include a material suitable for electromigration.

The e-fuse device may further include an interlayer insulating layer over the capping insulation layer and contacting a top surface of the exposed region, the interlayer insulating layer including a material suitable for electromigration.

A bottom surface and lateral surfaces of the cavity may be between the capping insulation layer and the metal pattern.

A bottom surface of the metal pattern and lateral surfaces of the barrier metal may define lateral surfaces and a top surface of the cavity.

### BRIEF DESCRIPTION OF THE DRAWINGS

Example embodiments will be more clearly understood from the following detailed description taken in conjunction with the accompanying drawings. FIGS. 1-28 represent non-limiting, example embodiments as described herein.

FIG. 1 is a schematic view illustrating an effect of electromigration in a program process of e-fuse devices according to example embodiments of the present inventive concepts;

FIG. 2 is a schematic view illustrating an effect of thermomigration in a program process of e-fuse devices according to example embodiments of the present inventive concepts;

FIG. 3 is a schematic view illustrating effects of electromigration and thermomigration in a program process of e-fuse devices according to example embodiments of the present inventive concepts;

FIG. 4 is a plan view illustrating a configuration of an e-fuse device according to example embodiments of the present inventive concepts;

FIG. 5 is a cross-sectional view illustrating the configuration of the e-fuse device according to example embodiments of the present inventive concepts, taken along the line A-A of FIG. 4;

FIGS. 6 to 11 are views illustrating intermediate process steps for explaining a method for manufacturing the e-fuse device according to example embodiments of the present inventive concepts;

FIG. 12 is a cross-sectional view illustrating a configuration of an e-fuse device according to example embodiments of the present inventive concepts;

FIG. 13 is a view illustrating an intermediate process step for explaining a method for manufacturing the e-fuse device according to example embodiments of the present inventive concepts;

FIG. 14 is a cross-sectional view illustrating a configuration of an e-fuse device according to example embodiments of the present inventive concepts;

FIGS. 15 and 16 are views illustrating intermediate process steps for explaining a method for manufacturing the e-fuse device according to example embodiments of the present inventive concepts;

FIG. 17 is a cross-sectional view illustrating a configuration of an e-fuse device according to example embodiments of the present inventive concepts;

FIGS. 18 to 20 are views illustrating intermediate process steps for explaining a method for manufacturing the e-fuse device according to example embodiments of the present inventive concepts;

FIG. 21 is a plan view illustrating a configuration of an e-fuse device according to example embodiments of the present inventive concepts;

FIG. 22 is a cross-sectional view illustrating the configuration of the e-fuse device according to example embodiments of the present inventive concepts, taken along the line B-B of FIG. 21;

FIGS. 23 to 25 are views illustrating intermediate process steps for explaining a method for manufacturing the e-fuse device according to example embodiments of the present inventive concepts;

FIG. 26 is a block diagram illustrating an exemplary memory system including semiconductor devices according to example embodiments of the present inventive concepts;

FIG. 27 is a block diagram illustrating an exemplary memory card including semiconductor devices according to example embodiments of the present inventive concepts; and

FIG. 28 is a block diagram illustrating an exemplary information processing system having a semiconductor device according to example embodiments of the present inventive concepts mounted therein.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto.

Example embodiments of the present inventive concepts relate to e-fuse devices and/or a method for manufacturing the same.

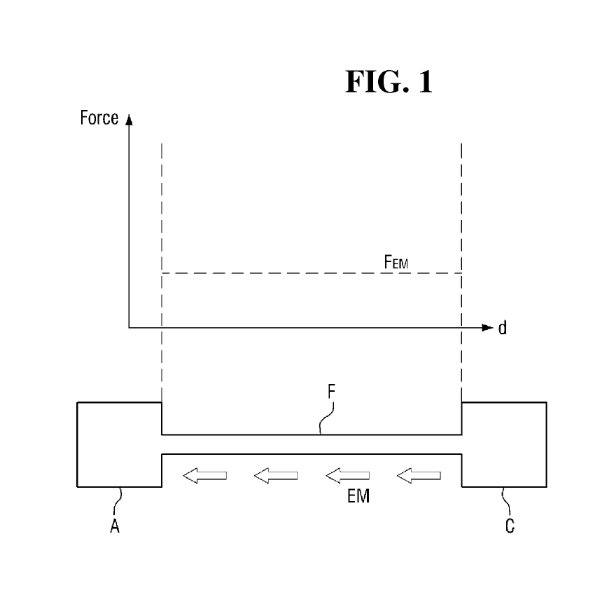

Hereinafter, a thermally-assisted electromigration mode used in a program process of e-fuse devices according to some example embodiments of the present inventive concepts will be described with reference to FIGS. 1 to 3.

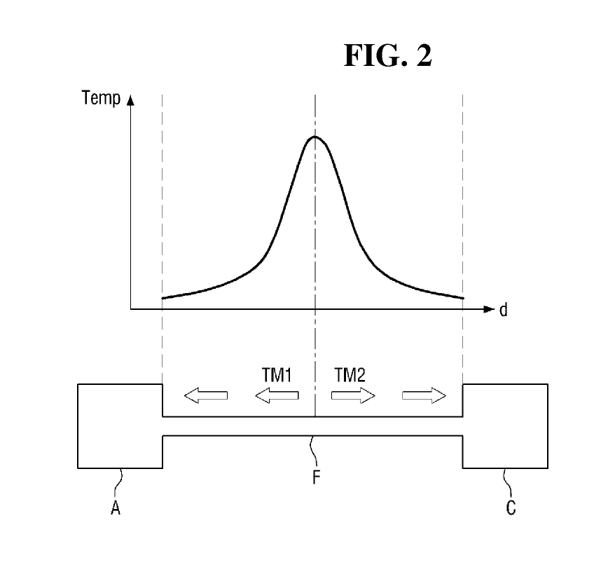

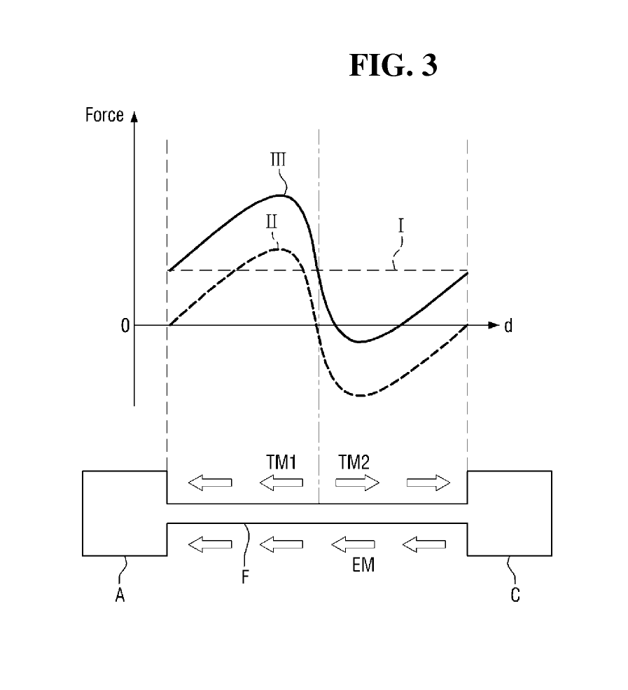

FIG. 1 is a schematic view illustrating an effect of eletromigration in a program process of e-fuse devices according to some example embodiments of inventive concepts, FIG. 2 is a schematic view illustrating an effect of thermomigration in a program process of e-fuse devices according to some example embodiments of the present inventive concepts and FIG. 3 is a schematic view illustrating effects of electromigration and thermomigration in a program process of e-fuse devices according to some example embodiments of the present inventive concepts.

Referring to FIG. 1, a fuse link F of each of e-fuse devices according to example embodiments of the present inventive concepts may have a linear structure or a stacked structure. However, for the sake of brevity and convenient explanation, the fuse link F is illustrated as a linear fuse link in FIGS. 1 to 3.

Programming of the e-fuse device includes providing a program current to the fuse link F by applying a set (or, predetermined) voltage between a cathode C and an anode A. For the programming of the e-fuse device, a negative voltage may be applied to the cathode C and a positive voltage may be applied to the anode A. Accordingly, electrons may migrate in the fuse link F in a direction ranging from the cathode C to the anode A. When the electrons migrate in the fuse link F, the electrons and atoms constituting the fuse link F may collide to cause an electromigration (EM) phenomenon.

In FIG. 1, a driving force based on the electromigration occurring in the fuse link F (that is, an electromotive force: F_{EM}) is uniformly supplied throughout the fuse link F, regardless of the position of the fuse link F, which is, however, provided only for the sake of brevity and convenient explanation, but example embodiments are not limited thereto. For example, the driving force FEM based on the electromigration occurring in the fuse link F may vary by varying cross-sectional areas of the fuse link F.

In addition, the fuse link F may be made of a metal such as tungsten, aluminum or copper. When a program current is supplied to the fuse link F, Joule's heat may be generated by the program current. The Joule's heat generated by the program current may form an uneven temperature distribution in the fuse link F. In the uneven temperature distribution, a temperature at the center part of the fuse link F may be highest. The uneven temperature distribution may cause thermomigration phenomena TM1 and TM2 of atoms in the fuse link F. The thermomigration phenomena include first thermomigration TM1 in which atoms migrate in a direction ranging from the center part of the fuse link F to the anode A, and second thermomigration TM2 in which atoms migrate in a direction ranging from the center part of the fuse link F to the cathode C.

Referring to FIG. 3, a driving force based on electromigration in the fuse link F (that is, an electromotive driving force F_{EM}) may be uniformly supplied throughout the fuse link F, regardless of the position of the fuse link F. In addition, because the fuse link F has an uneven temperature distribution, driving forces based on thermomigration (that is, a thermal driving force FTM) may be applied to the fuse link F in opposite directions from opposite sides of the center part of the fuse link F.

Between the anode A and the center part of the fuse link F, atomic migration based on the electromigration EM and atomic migration based on the first thermomigration TM1 are in the same direction. Therefore, when the electromigration EM and the thermomigration TM are added, a total driving force (FEM+TM) applied in the fuse link F may be increased.

However, between the cathode C and the center part of the fuse link F, atomic migration based on the electromigration EM and atomic migration based on the first thermomigration TM1 are in the opposite directions. Therefore, when the electromigration EM and the thermomigration TM are added, a total driving force (F_{EM+TM}) applied in the fuse link F may be decreased.

That is to say, as shown in FIG. 3, when the electromigration EM and the thermomigration TM are added, flux divergence, that is, non-uniform atomic flow rates, may be generated due to an uneven temperature distribution in the fuse link F. In addition, atoms may be depleted or accumulated in a region where the flux divergence occurs. In more detail, if an out-flowing flux of atoms is greater than an in-flowing flux of atoms in an arbitrary region of the fuse link F, voids may be formed due to depletion of atoms. Conversely, if an in-flowing flux is greater than an out-flowing flux of atoms in an arbitrary region of the fuse link F, atoms may accumulate, so that hill-locks may be formed. In such a manner, formation of voids based on the flux divergence may increase resistance of the fuse link F and the increased resistance of the fuse link F may program the e-fuse device.

As described above, void formation due to depletion of atoms can be facilitated by supplying larger flux divergence into the fuse link F in programming the e-fuse device.

Accordingly, the e-fuse device capable of providing larger flux divergence can be achieved by adjusting the total driving force supplied to the fuse link F. In addition, in designing the e-fuse device, a region where relatively large flux divergence can be provided is created in the fuse link F, thereby providing an e-fuse device, which can adjust a void formation spot.

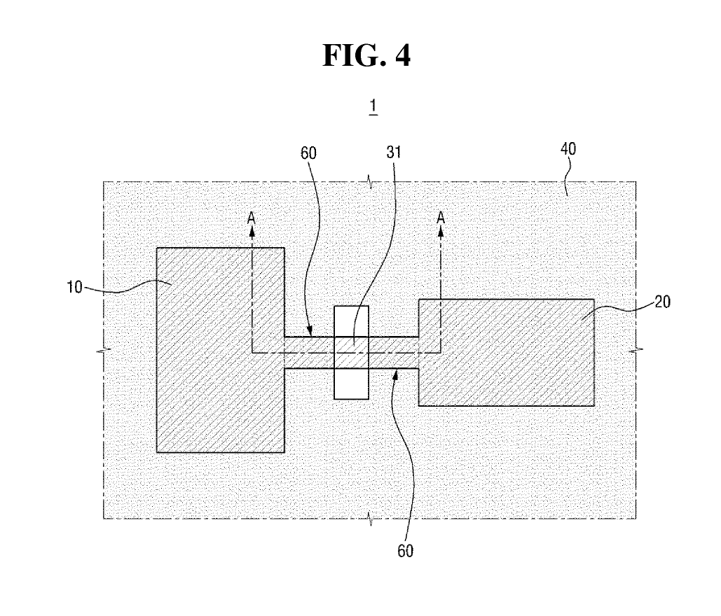

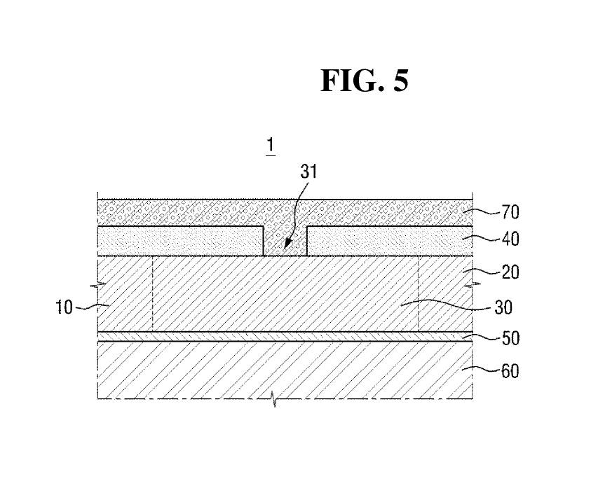

Next, an e-fuse device according to example embodiments of the present inventive concepts will be described with reference to FIGS. 4 and 5.

FIG. 4 is a plan view illustrating a configuration of an e-fuse device according to example embodiments of the present inventive concepts and FIG. 5 is a cross-sectional view illustrating the configuration of the e-fuse device according to example embodiments of the present inventive concepts, taken along the line A-A of FIG. 4.

Referring to FIGS. 4 and 5, an e-fuse device 1 according to example embodiments of the present inventive concepts includes a first interlayer insulation layer 60, a first electrode 10, a second electrode 20, a first metal pattern 30, a first barrier metal 50, a first capping insulation layer 40 and a first exposed region 31.

The first interlayer insulation layer 60 may include a low-k dielectric. The terminology “low-k dielectric” as used herein refers to a dielectric material having improved insulating capability, compared to silicon oxide (SiO₂) used as a semiconductor insulating material, and having a dielectric constant of 4.0 or less. The low-k dielectric may include, for example, fluorine-added SiO₂ (SiOF), an organic polymer fluorine resin, a polyimide-based resin or hydrogen-containing SOG.

The first interlayer insulation layer 60 may be formed on lateral surfaces and bottom surfaces of the first electrode 10, the second electrode 20 and the first metal pattern 30, but example embodiments of the present disclosure are not limited thereto.

The first electrode 10 may perform the same function as the cathode C shown in FIGS. 1 to 3. The second electrode 20 may perform the same function as the anode A shown in FIGS. 1 to 3. That is to say, the first electrode 10 and the second electrode 20 may be a cathode and an anode for programming the first metal pattern 30.

The first electrode 10 and the second electrode 20 may be formed at the same level with the first metal pattern 30. The first electrode 10 and the second electrode 20 may be integrally formed with the first metal pattern 30, but example embodiments of the present disclosure are not limited thereto. That is to say, the first electrode 10 and the second electrode 20 may be separately formed from the first metal pattern 30 to then be electrically connected. That is to say, the first electrode 10 and the second electrode 20 are not specifically limited in view of their forming methods so long as they are electrically connected by the first metal pattern 30. In addition, the first electrode 10 and the second electrode 20 are not specifically limited in view of their shapes and widths, either.

The first metal pattern 30 may perform the same function as the fuse link F shown in FIGS. 1 to 3. In FIGS. 4 and 5, the first metal pattern 30 is linear, but example embodiments of the present disclosure are not limited thereto. The first metal pattern 30 may include curved portions corresponding to the first electrode 10 and the second electrode 20.

The first metal pattern 30, the first electrode 10 and the second electrode 20 may be vertically positioned at the same level. The terminology “the same level” as used herein may be a concept encompassing an insignificant (or non-substantial) step difference. The first metal pattern 30, the first electrode 10 and the second electrode 20 may be all covered by the first capping insulation layer 40, but example embodiments of the present disclosure are not limited thereto. The first electrode 10 and the second electrode 20 may be positioned at different levels from the first metal pattern 30, and only the first metal pattern 30 may be covered by the first capping insulation layer 40.

The first metal pattern 30 may include a metal. Because the first metal pattern 30 needs to form a fuse, it may include, for example, Cu, Al or Ag, but example embodiments of the present disclosure are not limited thereto.

The first barrier metal 50 may be formed to make contact with lateral surfaces and a bottom surface of the first metal pattern 30. That is to say, the first barrier metal 50 may be formed between the first metal pattern 30 and the first interlayer insulation layer 60. The first barrier metal 50 may prevent the first interlayer insulation layer 60 and the first metal pattern 30 from making direct contact with each other.

The first barrier metal 50 may not be formed on a top surface of the first metal pattern 30. The first barrier metal 50 is a part including a seed metal for plating the first metal pattern 30. Accordingly, the first barrier metal 50 may be positioned on the lateral surface or bottom surface of the first metal pattern 30.

The first barrier metal 50 may be much (or substantially) thinner than the first metal pattern 30. In addition, the first barrier metal 50 may have a relatively uniform thickness. The first barrier metal 50 may include at least one of Ta, Co and Ru.

The first capping insulation layer 40 may be formed on the top surface of the first metal pattern 30. The first capping insulation layer 40 may make direct contact with the first metal pattern 30. As described above, the first capping insulation layer 40 may also be formed on a top surface of the first electrode 10 or the second electrode 20 and may cover the first electrode 10 or the second electrode 20 together with the first metal pattern 30.

The first capping insulation layer 40 may be an electrically non-conducting insulating layer. The first capping insulation layer 40 may include, for example, silicon nitride (SiN), but example embodiments of the present disclosure are not limited thereto.

The first capping insulation layer 40 may make contact with the top surface of the first metal pattern 30. However, a portion of the first capping insulation layer 40 may not make contact with the first metal pattern 30 and a portion of the remaining portion of the first capping insulation layer 40 may make contact with the first metal pattern 30. That is to say, a first exposed region 31 not making contact with the first capping insulation layer 40 may be formed on the top surface of the first metal pattern 30.

In FIGS. 4 and 5, the first exposed region 31 positioned at the center of the first metal pattern 30 is illustrated, but example embodiments of the present disclosure are not limited thereto. In addition, in FIGS. 4 and 5, the first exposed region 31 having a maximum width in a width direction of the first metal pattern 30 is illustrated, but example embodiments of the present disclosure are not limited thereto. That is to say, only portions of the first metal pattern 30 in length or width directions of the first metal pattern 30 may correspond to the first exposed region 31.

The second interlayer insulation layer 70 may be formed on the first capping insulation layer 40. The second interlayer insulation layer 70 may be formed on the first exposed region 31. The second interlayer insulation layer 70 may make direct contact with the first exposed region 31. That is to say, the second interlayer insulation layer 70 may be formed on the first exposed region 31 without the first capping insulation layer 40 so as to make direct contact with the first exposed region 31. The first exposed region 31 may come into perfect contact with the second interlayer insulation layer 70.

The second interlayer insulation layer 70 may include a low-k dielectric, like the first interlayer insulation layer 60. The terminology “low-k dielectric” as used herein refers to a dielectric material having improved insulating capability, compared to silicon oxide (SiO₂) used as a semiconductor insulating material, and having a dielectric constant of 4.0 or less. The low-k dielectric may include, for example, fluorine-added SiO₂ (SiOF), an organic polymer fluorine resin, a polyimide-based resin or hydrogen-containing SOG. The second interlayer insulation layer 70 may include the same material as the first interlayer insulation layer 60, but example embodiments of the present disclosure are not limited thereto.

In the first metal pattern 30 functioning as a fuse link, electrons in the first metal pattern 30 may migrate to then collide with atoms in the fuse link, and atomic migration may occur, which is referred to as electromigration. The electromigration may be considerably affected by the electric current flowing along a surface of the first metal pattern 30.

In detail, in a case where the surface of the first metal pattern 30 is formed of an electromigration (EM) friendly material, the electric current flowing along the surface of the first metal pattern 30 may increase. Therefore, the e-fuse device 1 according to example embodiments of the present inventive concepts may provide improved fusing characteristics of the first metal pattern 30 using the second interlayer insulation layer 70, which is more EM-friendly than the first capping insulation layer 40.

That is to say, the second interlayer insulation layer 70, rather than the first capping insulation layer 40, comes into contact with the first exposed region 31 of the first metal pattern 30, thereby achieving a low-voltage fusing characteristic to enable fusing at a lower voltage, compared to a case where the first capping insulation layer 40 comes into perfect contact with the top surface of the first metal pattern 30.

In addition, a fusing position may be adjusted by adjusting the position of the first exposed region 31. That is to say, the current flowing in the first exposed region 31 while the second interlayer insulation layer 70 makes contact with the first exposed region 31 may be increased, compared to a case where the first capping insulation layer 40 comes into contact with the first exposed region 31. Accordingly, fusing may be achieved at a lower voltage and fusing may be performed at the first exposed region 31. Therefore, the fusing position can be accurately adjusted by forming the first exposed region 31 at a desired position.

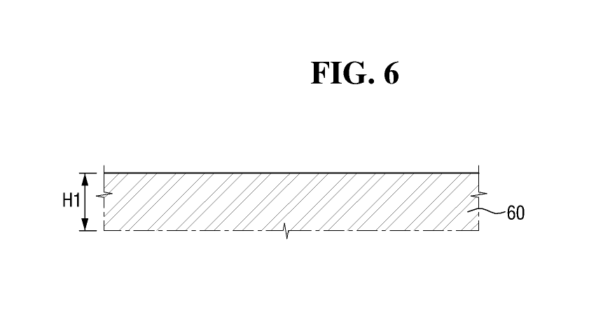

Next, a method for manufacturing the e-fuse device according to example embodiments of the present inventive concepts will be described with reference to FIGS. 6 to 11.

FIGS. 6 to 11 are views illustrating intermediate process steps for explaining a method for manufacturing the e-fuse device according to example embodiments of the present inventive concepts. FIGS. 6 to 11 illustrate sectional views taken along the line A-A of FIG. 4.

Referring first to FIG. 6, a first interlayer insulation layer 60 is formed. The first interlayer insulation layer 60 may be formed on a semiconductor substrate. The semiconductor substrate may be provided immediately under the first interlayer insulation layer 60, but another kind of an underlying semiconductor device may exist. That is to say, in a case where another underlying semiconductor device exists, the first interlayer insulation layer 60 may be electrically separated from a first metal pattern 30 to be formed later.

The first interlayer insulation layer 60 may include a low-k dielectric. The term “low-k dielectric” used herein refers to a dielectric material having improved insulating capability, compared to silicon oxide (SiO₂) used as a semiconductor insulating material, and having a dielectric constant of 4.0 or less.

The low-k dielectric may include, for example, fluorine-added SiO₂ (SiOF), an organic polymer fluorine resin, a polyimide-based resin or hydrogen-containing SOG. The second interlayer insulation layer 70 may include the same material as the first interlayer insulation layer 60, but example embodiments of the present disclosure are not limited thereto.

The first interlayer insulation layer 60 may have a sufficiently large thickness H1 at an initial stage. Then, the first interlayer insulation layer 60 may be partially removed to form the first metal pattern 30 shown in FIG. 5 in a subsequent process.

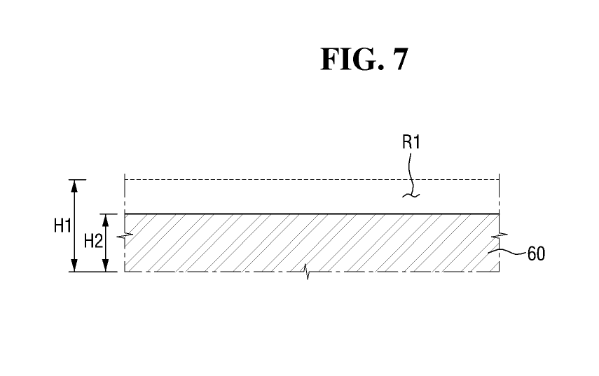

Next, referring to FIG. 7, a first recess R1 is formed in the first interlayer insulation layer 60. In FIG. 7, the first interlayer insulation layer 60 having the entirely reduced thickness is illustrated, which is, however, based on the characteristic of FIG. 7 as an enlarged view. The first interlayer insulation layer 60 includes the first recess R1 having sidewalls and a bottom surface.

The bottom surface of the first recess R1 may have a thickness H2 smaller than the thickness H1 of the first interlayer insulation layer 60. A non-recessed portion of the first interlayer insulation layer 60 may maintain the thickness H1 of the first interlayer insulation layer 60, which is not illustrated in FIG. 7, though.

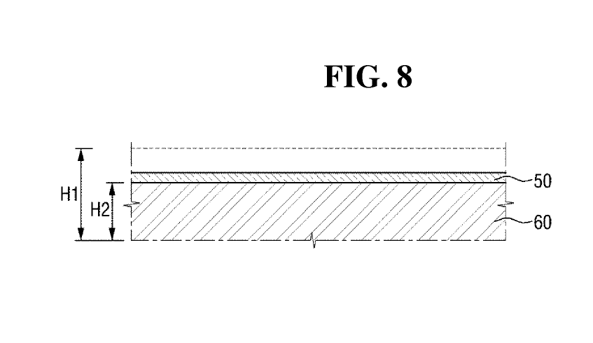

Next, referring to FIG. 8, a first barrier metal 50 is formed on the bottom surface and sidewalls of the first recess R1. In FIG. 8, the first barrier metal 50 formed only on the bottom surface of the first recess R1 is illustrated, which is, however, based on the characteristic of FIG. 8 as an enlarged view. The first barrier metal 50 may also be formed on the sidewalls of the first recess R1.

The first barrier metal 50 may be conformally formed along the bottom surface and sidewalls of the first recess R1. The first barrier metal 50 may also be formed on a top surface of the first interlayer insulation layer 60, rather than the first recess R1, to then be completely removed through planarization, and may remain only inside the first recess R1.

The first barrier metal 50 may be much thinner than the first metal pattern 30. In addition, the first barrier metal 50 may have a relatively uniform thickness. The first barrier metal 50 may include at least one of Ta, Co and Ru.

The first barrier metal 50 may include a seed metal for electroplating the first metal pattern 30. In detail, the seed metal may be formed on the first barrier metal 50. The seed metal may be a metal for forming the first metal pattern 30. For example, the seed metal may be Cu, but example embodiments of the present disclosure are not limited thereto.

The first metal pattern 30 may include Cu, Al or Ag. In such a case, the first metal pattern 30 may be formed by a method other than electroplating.

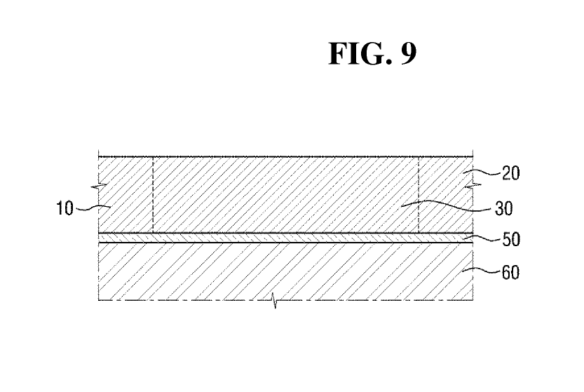

Next, referring to FIG. 9, a first metal pattern 30 is formed. The first metal pattern 30 may include a metal. Because the first metal pattern 30 needs to form a fuse, it may include, for example, Cu, Al or Ag, but example embodiments of the present disclosure are not limited thereto.

If the first metal pattern 30 includes Cu, it may be formed by electroplating. The electroplating may be performed by the seed metal formed on a top surface of the first barrier metal 50.

The first metal pattern 30 may be formed with the first electrode 10 or the second electrode 20, but example embodiments of the present disclosure are not limited thereto. In FIG. 9, the first metal pattern 30 formed with the first electrode 10 and the second electrode 20 is illustrated by way of example. Therefore, the first metal pattern 30, the first electrode 10 and the second electrode 20 may all be integrally formed.

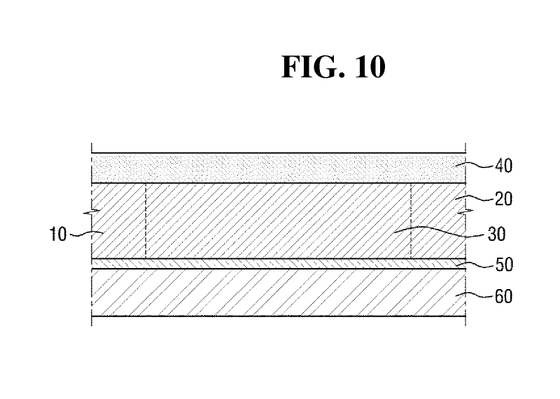

Next, referring to FIG. 10, a first capping insulation layer 40 is formed on a top surface of the first metal pattern 30. In a case where the first metal pattern 30 is formed with the first electrode 10 or the second electrode 20 and is vertically formed at the same level with the first electrode 10 or the second electrode 20, the first capping insulation layer 40 may be formed on the first metal pattern 30, the first electrode 10 and the second electrode 20 at the same time.

Here, the first capping insulation layer 40 may come into perfect contact with the top surface of the first metal pattern 30. That is to say, a region not making contact with the first capping insulation layer 40 does not exist on the top surface of the first metal pattern 30.

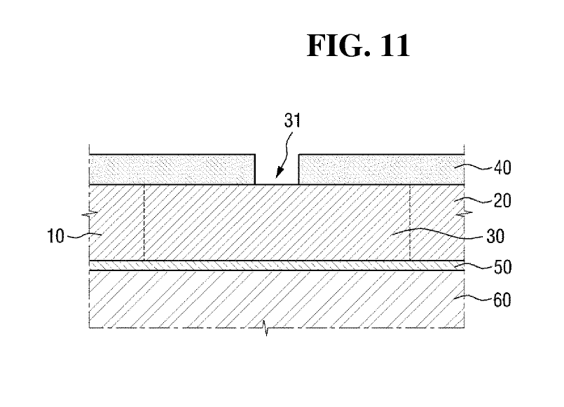

Next, referring to FIG. 11, a portion of the first capping insulation layer 40 is etched, thereby exposing the first exposed region 31 of the first metal pattern 30. In FIG. 1, the first exposed region 31 positioned at the center of the first metal pattern 30 is illustrated, but example embodiments of the present disclosure are not limited thereto. In addition, in FIG. 11, the first exposed region 31 having a maximum width in a width direction of the first metal pattern 30 is illustrated, but example embodiments of the present disclosure are not limited thereto. That is to say, only portions of the first metal pattern 30 in length or width directions of the first metal pattern 30 may correspond to the first exposed region 31.

Referring again to FIG. 5, a second interlayer insulation layer 70 is formed on the first capping insulation layer 40 and the first exposed region 31. The second interlayer insulation layer 70 may be formed on the first capping insulation layer 40. The second interlayer insulation layer 70 may also be formed on the first exposed region 31. The second interlayer insulation layer 70 may make direct contact with the first exposed region 31. That is to say, the second interlayer insulation layer 70 may be formed on the first exposed region 31 without the first capping insulation layer 40 so as to make direct contact with the first exposed region 31. The first exposed region 31 may come into perfect contact with the second interlayer insulation layer 70.

The second interlayer insulation layer 70 may include a low-k dielectric, like the first interlayer insulation layer 60. The terminology “low-k dielectric” as used herein refers to a dielectric material having improved insulating capability, compared to silicon oxide (SiO₂) used as a semiconductor insulating material, and having a dielectric constant of 4.0 or less. The low-k dielectric may include, for example, fluorine-added SiO₂ (SiOF), an organic polymer fluorine resin, a polyimide-based resin or hydrogen-containing SOG. The second interlayer insulation layer 70 may include the same material as the first interlayer insulation layer 60, but example embodiments of the present disclosure are not limited thereto.

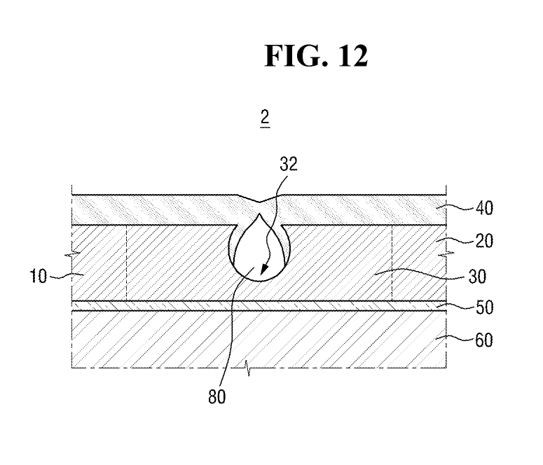

Next, an e-fuse device according to example embodiments of the present inventive concepts will be described with reference to FIG. 12. Because example embodiments of the present inventive concepts re substantially the same the previously-described example embodiments of the present inventive concepts, except for an exposed region and an air gap, repeated descriptions thereof will be briefly given or will not be given for the sake of brevity.

FIG. 12 is a cross-sectional view illustrating a configuration of an e-fuse device according to example embodiments of the present inventive concepts.

Referring to FIG. 12, an e-fuse device 2 according to example embodiments of the present inventive concepts includes a second exposed region 32 and a first air gap 80.

The top surface of the first metal pattern 30 may include a second exposed region 32. In detail, the first metal pattern 30 may include a recessed portion in the first metal pattern 30. The first metal pattern 30 may have the second exposed region 32 formed on a top surface of its recessed portion. The second exposed region 32 may be a portion of the top surface of the recessed first metal pattern 30.

That is to say, the first metal pattern 30 may include a recessed portion. The first capping insulation layer 40 may be formed on the first metal pattern 30 including the recessed portion. The first capping insulation layer 40 may be formed on the recessed portion to cover the recessed portion. The first capping insulation layer 40 may be deposited using a method having a poor step coverage characteristic. The first capping insulation layer 40 may be formed using, for example, chemical vapor deposition (CVD) or plasma enhanced chemical vapor deposition (PECVD), but example embodiments of the present disclosure are not limited thereto.

The first capping insulation layer 40 formed using the method having a poor step coverage characteristic may include the first air gap 80 formed in the recessed portion of the first metal pattern 30.

A top surface of the first air gap 80 may correspond to the first capping insulation layer 40 and a bottom surface of the first air gap 80 may correspond to the second exposed region 32. Lateral surfaces of the first air gap 80 may correspond to the first capping insulation layer 40 and the second exposed region 32. That is to say, the first capping insulation layer 40 may flow along the recessed portion up to the lateral surfaces of the first air gap 80, forming the first capping insulation layer 40, but example embodiments of the present disclosure are not limited thereto. An area of the second exposed region 32 occupied in the first air gap 80 may vary according to the step coverage capacity of the first capping insulation layer 40.

Electromigration of a fuse link may be considerably affected by the electric current flowing along a surface of the first metal pattern 30. In addition, in a case where the surface of the first metal pattern 30 is formed of an electromigration (EM) friendly material, the electric current flowing along the surface of the first metal pattern 30 may increase.

Among materials being in contact with the top surface of the first metal pattern 30, the air has high electromigration affinity. That is to say, the air derived from the first air gap 80, rather than from the first capping insulation layer 40, comes into contact with the second exposed region 32 of the first metal pattern 30, thereby achieving a low-voltage fusing characteristic to enable fusing at a lower voltage, compared to a case where the first capping insulation layer 40 comes into perfect contact with the top surface of the first metal pattern 30.

In addition, a fusing position may be adjusted by adjusting the position of the second exposed region 32. That is to say, the current flowing in the second exposed region 32 while the second interlayer insulation layer 70 makes contact with the second exposed region 32 may be increased, compared to a case where the first capping insulation layer 40 comes into contact with the second exposed region 32. Accordingly, fusing may be achieved at a lower voltage and fusing may be performed at the second exposed region 32. Therefore, the fusing position can be accurately adjusted by forming the second exposed region 32 at a desired position.

Next, a method for manufacturing the e-fuse device according to example embodiments of the present inventive concepts will be described with reference to FIGS. 6 to 9, 12 and 13. Because the manufacturing method according to example embodiments of the present inventive concepts is substantially the same with the manufacturing method according to example embodiments of the present inventive concepts, repeated descriptions thereof will be briefly given or will not be given.

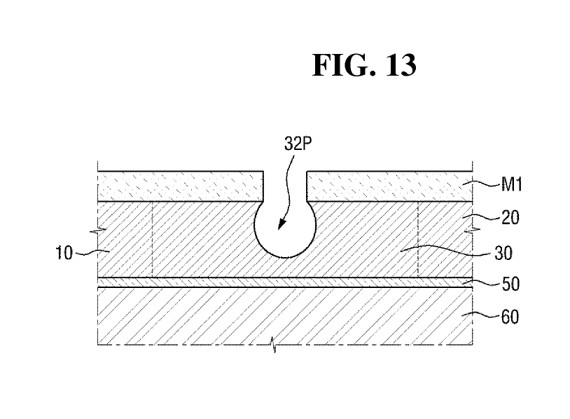

FIG. 13 is a view illustrating an intermediate process step for explaining a method for manufacturing the e-fuse device according to example embodiments of the present inventive concepts. FIG. 13 illustrates a sectional view taken along the line A-A of FIG. 4.

First, the first interlayer insulation layer 60, the first barrier metal 50 and the first metal pattern 30 are formed in the same manner as in example embodiments of the present inventive concepts.

Next, referring to FIG. 13, a first mask M1 is formed on a remaining portion of the first metal pattern 30, excluding the portion of the first metal pattern 30. The first mask M1 is formed for the purpose of protecting the remaining portion of the first metal pattern 30, excluding a potential portion of the second exposed region 32 to be formed in a subsequent process. The first mask M1 may be used to selectively etch the first metal pattern 30. The first mask M1 may include, for example, a photoresist PR, but example embodiments of the present disclosure are not limited thereto.

Next, the first metal pattern 30 is partially etched using the first mask M1. The first metal pattern 30 may be etched through a portion of the first metal pattern 30, which is not masked by the first mask M1 but is exposed. As the result of the etching, a recess may be formed, thereby forming a pre-second exposed region 32p. Here, the etching may be, for example, wet etching, but not limited thereto.

The pre-second exposed region 32p may include a portion to be formed as the second exposed region 32 in a subsequent process. However, the pre-second exposed region 32p may also include a portion that is not exposed by the first capping insulation layer 40 in a subsequent process.

The first mask M1 may be removed after the etching is finished.

Next, referring again to FIG. 12, a first capping insulation layer 40 is formed on the first metal pattern 30. The first capping insulation layer 40 may be formed to make contact with a remaining portion of the top surface of the first metal pattern 30, excluding the pre-second exposed region 32p. Because there is a step difference between the pre-second exposed region 32p and a top surface of another first metal pattern 30, the pre-second exposed region 32p may not come into perfect contact with the first capping insulation layer 40 but may come into partial contact with the first capping insulation layer 40, which is because the first capping insulation layer 40 is formed by the method having a poor step coverage characteristic.

While the first capping insulation layer 40 is formed, the first air gap 80 having the second exposed region 32 as its bottom surface and/or lateral surfaces may be formed between the first capping insulation layer 40 and the first metal pattern 30.

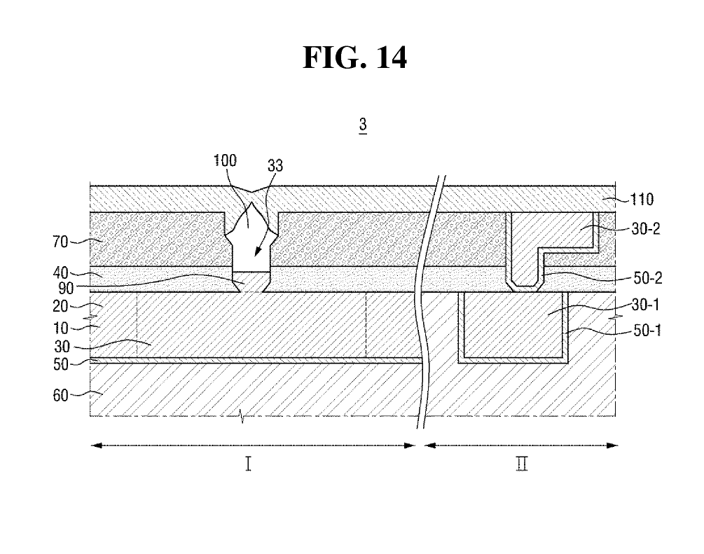

Hereinafter, an e-fuse device according to example embodiments of the present inventive concepts will be described with reference to FIG. 14. In the following description, repeated descriptions of the above example embodiments of the present inventive concepts will be briefly given or will not be given.

FIG. 14 is a cross-sectional view illustrating a configuration of an e-fuse device according to example embodiments of the present inventive concepts.

Referring to FIG. 14, an e-fuse device 3 according to example embodiments of the present inventive concepts may further include a second metal pattern 30-1, a second barrier metal 50-1, a third metal pattern 30-2, a third barrier metal 50-2, a first metal pattern rising part 90, a second capping insulation layer 110, a third exposed region 33 and a second air gap 100.

The first interlayer insulation layer 60 includes a first region I and a second region II. The first region I may be a region where an e-fuse structure is formed and the second region II may be a region where a wiring structure based on a general back end of line (BEOL) process is formed.

The first metal pattern 30 and the first barrier metal 50 may be formed in the first region I and the second metal pattern 30-1 and the second barrier metal 50-1 may be formed in the second region II at the same vertical level as the first metal pattern 30 and the first barrier metal 50.

The second metal pattern 30-1 may be a general wiring pattern made of a metal. The metal may include Cu, Al or Ag, like the first metal pattern 30. The second barrier metal 50-1 may be thinly formed on lateral surfaces and a bottom surface of the second metal pattern 30-1.

The first capping insulation layer 40 may be formed on the first metal pattern 30 and the second metal pattern 30-1. The first capping insulation layer 40 may cover the first metal pattern 30 and the second metal pattern 30-1 at the same time.

The second interlayer insulation layer 70 may be formed on the first capping insulation layer 40. The second interlayer insulation layer 70 may be formed, regardless of the region. That is to say, the second interlayer insulation layer 70 may be formed on the first region I or the second region II.

A removed portion may be formed in the first region I to allow the first capping insulation layer 40 and the second interlayer insulation layer 70 to simultaneously pass through the removed portion. As the result, a third exposed region 33 may be formed on the top surface of the first metal pattern 30.

In detail, the third exposed region 33 may be formed to be higher than another top surface of the first metal pattern 30. The third exposed region 33 may correspond to a top surface of the first metal pattern rising part 90. That is to say, the first metal pattern rising part 90 may be formed in the removed portion of the first capping insulation layer 40. This may be achieved by removing a portion of the first capping insulation layer 40 and raising the exposed portion by electroplating.

A height of the first metal pattern rising part 90 may be lower than a top surface of the first capping insulation layer 40, but example embodiments of the present disclosure are not limited thereto.

The second capping insulation layer 110 may be formed on the third exposed region 33. The second capping insulation layer 110 may be formed on a top surface of the second interlayer insulation layer 70. The second capping insulation layer 110 may be formed to make contact with the top surface of a remaining portion of the second interlayer insulation layer 70, the remaining portion excluding the removed portion. Because there is a step difference between the third exposed region 33 and a top surface of another second interlayer insulation layer 70, the third exposed region 33 may not come into perfect contact with the second capping insulation layer 110, which is because the second capping insulation layer 110 is formed by the method having a poor step coverage characteristic.

While the second capping insulation layer 110 is formed, a second air gap 100 having the third exposed region 33 as its bottom surface and/or lateral surfaces may be formed between the second capping insulation layer 110 and the first metal pattern rising part 90.

A top surface of the second air gap 100 may correspond to the second capping insulation layer 110 and a bottom surface of the second air gap 100 may correspond to the third exposed region 33. Lateral surfaces of the second air gap 100 may correspond to the second capping insulation layer 110 and the second interlayer insulation layer 70. In addition, because a top surface of the third exposed region 33 may be higher than a top surface of the first capping insulation layer 40, the first capping insulation layer 40 may also form the lateral surfaces of the second air gap 100. An area of the second exposed region 32 occupied in the second air gap 100 may vary according to the step coverage capacity of the second capping insulation layer 110.

The third metal pattern 30-2 and the third barrier metal 50-2 may be formed in the second region II. The third metal pattern 30-2 and the third barrier metal 50-2 may be formed while passing through the second interlayer insulation layer 70. The third metal pattern 30-2 and the third barrier metal 50-2 may be electrically connected to the second metal pattern 30-1.

The third metal pattern 30-2 and the third barrier metal 50-2 may be vertically positioned at the same level with the second air gap 100. That is to say, the second capping insulation layer 110 may be formed on the second air gap 100 and the third metal pattern 30-2 at the same time.

Next, a method for manufacturing the e-fuse device according to example embodiments of the present inventive concepts will be described with reference to FIGS. 6 to 10 and 14 to 16. In the following description, repeated descriptions of the manufacturing methods according to the above example embodiments of the present inventive concepts will be briefly given or will not be given for the sake of brevity.

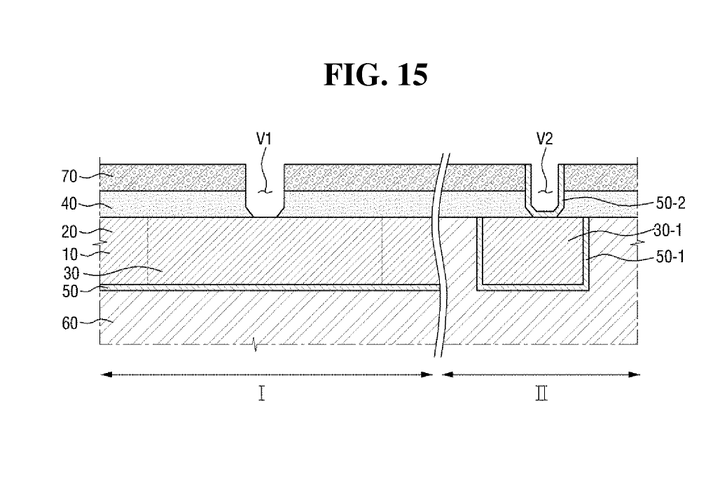

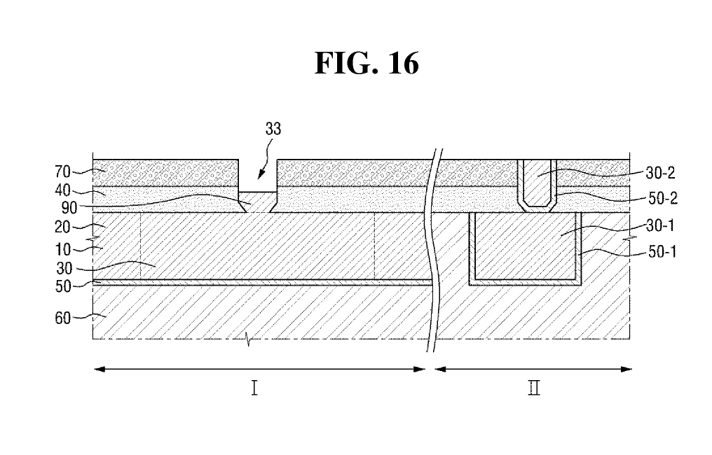

FIGS. 15 and 16 are views illustrating intermediate process steps for explaining a method for manufacturing the e-fuse device according to example embodiments of the present inventive concepts. FIGS. 15 and 16 illustrate sectional views taken along the line A-A of FIG. 4.

First, the first interlayer insulation layer 60, the first barrier metal 50 and the first metal pattern 30 are formed in the first region I in the same manner as in the first embodiment, as shown in FIGS. 6 to 9. Here, the second metal pattern 30-1 and the second barrier metal 50-1 shown in FIGS. 14 to 16 may also be formed in the second region II at the same time.

Next, referring to FIG. 15, the second interlayer insulation layer 70 is formed on both of the first region I and the second region II. Unlike in the above example embodiments, the second interlayer insulation layer 70 makes contact with the first capping insulation layer 40 while not making the first metal pattern 30.

Next, a first via V1 is formed in the first region I and a second via V2 is formed in the second region II.

The first via V1 may be formed in the first region I. The first via V1 may be formed while passing (or extending) through the second interlayer insulation layer 70 and the first capping insulation layer 40. The first via V1 may expose a top surface of the first metal pattern 30.

The second via V2 may be formed in the second region II. The second via V2 may be formed while passing (or extending) through the second interlayer insulation layer 70 and the first capping insulation layer 40. The second via V2 may expose a top surface of the second metal pattern 30-1.

Next, the third barrier metal 50-2 is formed on a bottom surface and lateral surfaces of the second via V2. The third barrier metal 50-2 may be conformally formed along the bottom surface and lateral surfaces of the second via V2. The third barrier metal 50-2 may include a seed metal for electroplating the third metal pattern 30-2 to be formed later, as shown in FIG. 16. The seed metal may include, for example, Cu, but example embodiments of the present disclosure are not limited thereto.

The first region I may remain without forming a barrier metal nor a seed metal. That is to say, no layer may be formed on the bottom surface and lateral surfaces of the first via V1.

Next, referring to FIG. 16, the third metal pattern 30-2 is formed by electroplating, and the first metal pattern rising part 90 is formed. In the second region II, the third metal pattern 30-2 may fully fill the second via V2 by the third barrier metal 50-2 in the second via V2.

In the first region I, the top surface of the first metal pattern 30, exposed by the first via V1 and forming the bottom surface of the first via V1, may form the first metal pattern rising part 90 by the electroplating. The first metal pattern rising part 90 may have a lower top surface than the third metal pattern 30-2. Therefore, the first via V1 may not be completely filled but may be only partially filled.

The top surface of the first metal pattern rising part 90 may form the third exposed region 33. The top surface of the third exposed region 33 may correspond to the bottom surface of the first via V1.

Next, referring again to FIG. 14, the second capping insulation layer 110 may be formed on the third exposed region 33, the second interlayer insulation layer 70 and the third metal pattern 30-2. Here, the second air gap 100 may be formed in the first via V1 by the method having a poor step coverage characteristic.

A top surface of the second air gap 100 may correspond to the second capping insulation layer 110 and a bottom surface of the second air gap 100 may correspond to the third exposed region 33. Lateral surfaces of the second air gap 100 may correspond to the second capping insulation layer 110 and the second interlayer insulation layer 70.

Accordingly, in the e-fuse device 3 according to example embodiments of the present inventive concepts, the air derived from the second air gap 100, rather than from the first capping insulation layer 40, comes into contact with the third exposed region 33 of the first metal pattern 30, thereby achieving a low-voltage fusing characteristic to enable fusing at a lower voltage, compared to a case where the first capping insulation layer 40 comes into perfect contact with the top surface of the first metal pattern 30.

In addition, a fusing position may be adjusted by adjusting the position of the third exposed region 33. That is to say, the current flowing in the third exposed region 33 while the second interlayer insulation layer 70 makes contact with the third exposed region 33 may be increased, compared to a case where the first capping insulation layer 40 comes into contact with the third exposed region 33. Accordingly, fusing may be achieved at a lower voltage and fusing may be performed at the third exposed region 33. Therefore, the fusing position can be accurately adjusted by forming the third exposed region 33 at a desired position.

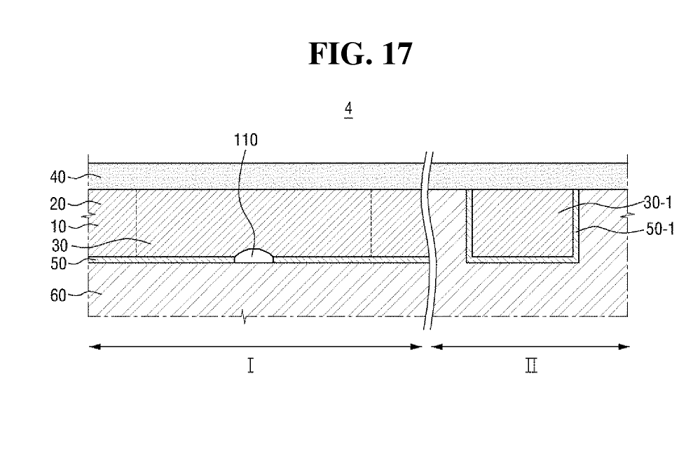

Next, an e-fuse device according to example embodiments of the present inventive concepts will be described with reference to FIG. 17. In the following description, repeated descriptions of the above example embodiments of the present inventive concepts will be briefly given or will not be given for the sake of brevity.

FIG. 17 is a cross-sectional view illustrating a configuration of an e-fuse device according to example embodiments of the present inventive concepts.

Referring to FIG. 17, an e-fuse device 4 according to example embodiments of the present inventive concepts may further include a third air gap 110.

A top surface of the third air gap 110 may correspond to the second capping insulation layer 110 and a bottom surface of the third air gap 110 may correspond to the third exposed region 33. Lateral surfaces of the third air gap 110 may correspond to the second capping insulation layer 110 and the second interlayer insulation layer 70. That is to say, unlike in the above example embodiments, the third air gap 110 may be an air gap formed on the bottom surface of the first metal pattern 30. Therefore, the top surface of the first metal pattern 30, instead of the first barrier metal 50, may come into contact with the air.

Accordingly, the e-fuse device 4 according to example embodiments of the present inventive concepts can achieve a low-voltage fusing characteristic to enable fusing at a lower voltage, compared to a case where the f first barrier metal 50 comes into perfect contact with the bottom surface of the first metal pattern 30.

In addition, a fusing position may be adjusted by adjusting the position of the third air gap 110. That is to say, the current flowing in the bottom surface of the first metal pattern 30 while the first interlayer insulation layer 60 makes contact with the third air gap 110 may be increased. Accordingly, fusing may be achieved at a lower voltage and fusing may be performed at the third air gap 110. Therefore, the fusing position can be accurately adjusted by forming the third air gap 110 at a desired position.

Next, a method for manufacturing the e-fuse device according to example embodiments of the present inventive concepts will be described with reference to FIGS. 6, 7 and 17 to 20. In the following description, repeated descriptions of the manufacturing methods according to the above example embodiments of the present inventive concepts will be briefly given or will not be given for the sake of brevity.

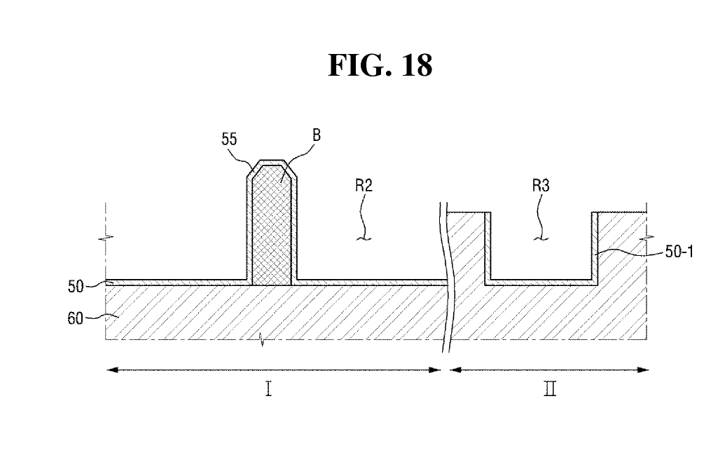

FIGS. 18 to 20 are views illustrating intermediate process steps for explaining a method for manufacturing the e-fuse device according to example embodiments of the present inventive concepts. FIGS. 18 to 20 illustrate sectional views taken along the line A-A of FIG. 4.

First, the first interlayer insulation layer 60 and the second recess R2 are formed in the first region I in the same manner as in example embodiments of the present inventive concepts, as shown in FIGS. 6 and 7. At this time, the third recess R3 may also be formed in the second region II at the same time with the first interlayer insulation layer 60 and the second recess R2.

Next, referring to FIG. 18, a blocking pattern B protruding from a bottom surface of the second recess R2 is formed in the first region I. The blocking pattern B may later be removed. The blocking pattern B may not be specifically limited in view of its shape but may be shaped to vertically extend. The blocking pattern B may be lifted off in a later process.

Next, the first barrier metal 50 and the second barrier metal 50-1 are formed on bottom and lateral surfaces of the second recess R2 and the third recess R3, respectively. Here, the fourth barrier metal 55 may also be formed on top and lateral surfaces of the blocking pattern B.

The fourth barrier metal 55 may constitute a portion of the first barrier metal 50. The fourth barrier metal 55 may be removed in a later process when the blocking pattern B is removed.

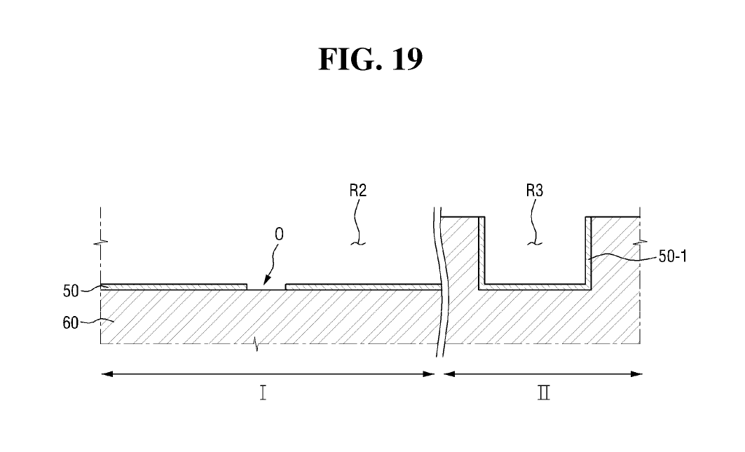

Next, referring to FIG. 19, the blocking pattern B and the fourth barrier metal 55 are removed. If the blocking pattern B is removed by a lift-off process, the fourth barrier metal 55 may also be removed. Accordingly, an open region O not in contact with the first barrier metal 50 may be formed on the bottom surface of the first recess R1. The open region O may expose the top surface of the first interlayer insulation layer 60.

Each of the first, second and fourth barrier metals may include a seed metal. The seed metal may be a metal for forming the first metal pattern 30 and the second metal pattern 30-1 by electroplating. For example, the seed metal may be Cu, but example embodiments of the present inventive concepts are not limited thereto.

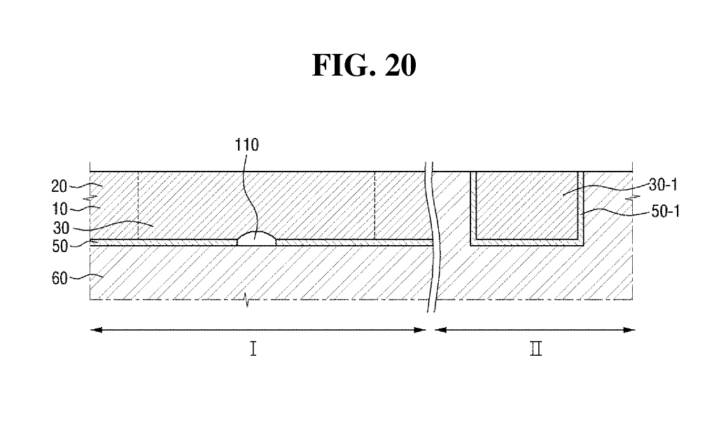

Next, referring to FIG. 20, electroplating is performed on the second recess R2 and the third recess R3 to form the first metal pattern 30 and the second metal pattern 30-1, while forming the third air gap 110 on the bottom surface of the first metal pattern 30. The electroplating is a process for forming a metal pattern based on a seed metal. However, an air gap may be formed in a region without a seed metal. That is to say, because a barrier metal or a seed metal is not formed in the open region O, the first metal pattern 30 may not be formed by electroplating, and the third air gap 110 may be formed, instead.

Next, referring back to FIG. 17, the first capping insulation layer 40 may be formed on the first metal pattern 30 and the second metal pattern 30-1 at the same time.

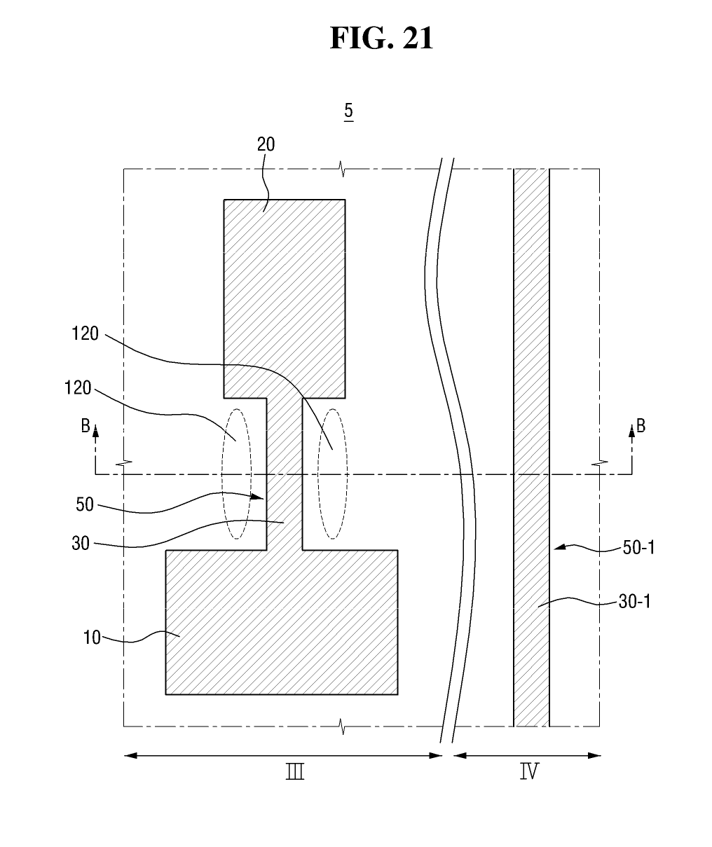

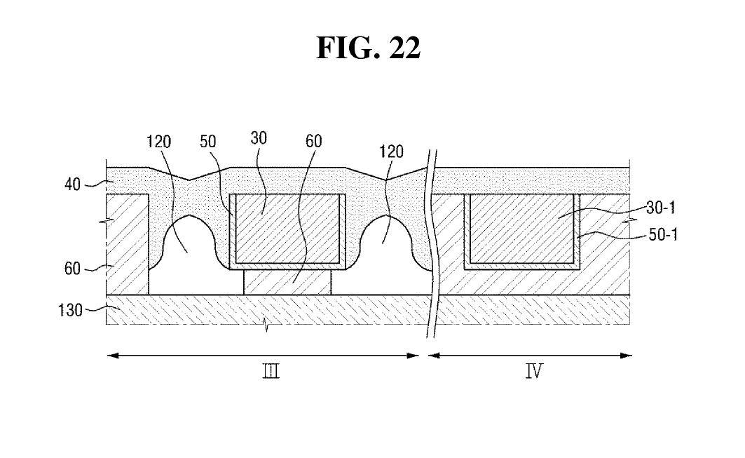

Next, an e-fuse device according to example embodiments of the present inventive concepts will be described with reference to FIGS. 21 and 22. In the following description, repeated descriptions of the above example embodiments of the present inventive concepts will be briefly given or will not be given.

FIG. 21 is a plan view illustrating a configuration of an e-fuse device according to example embodiments of the present inventive concepts, and FIG. 22 is a cross-sectional view illustrating the configuration of the e-fuse device according to example embodiments of the present inventive concepts, taken along the line B-B of FIG. 21.

Referring to FIGS. 21 and 22, an e-fuse device 5 according to example embodiments of the present inventive concepts includes an etch stop layer 130 and a fourth air gap 120.

The etch stop layer 130 may be formed on a third region III and a fourth region IV. The etch stop layer 130 may be formed immediately under the first interlayer insulation layer 60. When the first interlayer insulation layer 60 is etched, the etch stop layer 130 may function as an ending point of etching.

The etch stop layer 130 may include a silicon oxide, such as borosilica glass (BSG), phosphosilica glass (PSG), borophosphosilica glass (BPSG), undoped silica glass (USG), tetra ethyl ortho silicate (TEOS), or high density plasma-CVD (HDP-CVD). The etch stop layer 130 may include SiON or SiN.

The fourth air gap 120 may be formed to be parallel with a length direction of the first metal pattern 30. The phrase, “being parallel” as used herein may encompass having an insignificant (or non-substantial) angle difference from being in perfect parallel.

The fourth air gap 120 may be formed on lateral surfaces of the first metal pattern 30. The fourth air gap 120 may include a plurality of fourth air gaps, but example embodiments of the present inventive concepts are not limited thereto. However, it is most preferable to form the fourth air gaps 120 on opposite lateral surfaces of the first metal pattern 30, which will now be described.

A top surface of the fourth air gap 120 may correspond to the first capping insulation layer 40 and a bottom surface of the fourth air gap 120 may correspond to the etch stop layer 130. Lateral surfaces of the fourth air gap 120 may correspond to the first interlayer insulation layer 60 and the first capping insulation layer 40.

The fourth air gap 120 may not come into contact with the first metal pattern 30. The fourth air gap 120 may not increase the electric current flowing on a surface of the first metal pattern 30. However, the fourth air gap 120 may be formed for the purpose of preserving the temperature of the first metal pattern 30.

That is to say, as described above, an e-fuse device is considerably affected by the temperature. A driving force of the e-fuse device is generated by thermomigration. In the e-fuse device 5 according to example embodiments of the present inventive concepts, Joule's heat generated from the first metal pattern 30 may be preserved by the fourth air gaps 120 formed at opposite sides. Accordingly, heat integration of the e-fuse device 5 according to example embodiments of the present inventive concepts can be enhanced.

Next, a method for manufacturing the e-fuse device according to example embodiments of concepts will be described with reference to FIGS. 22 to 25. In the following description, repeated descriptions of the manufacturing methods according to the above example embodiments of the present inventive concepts will be briefly given or will not be given.

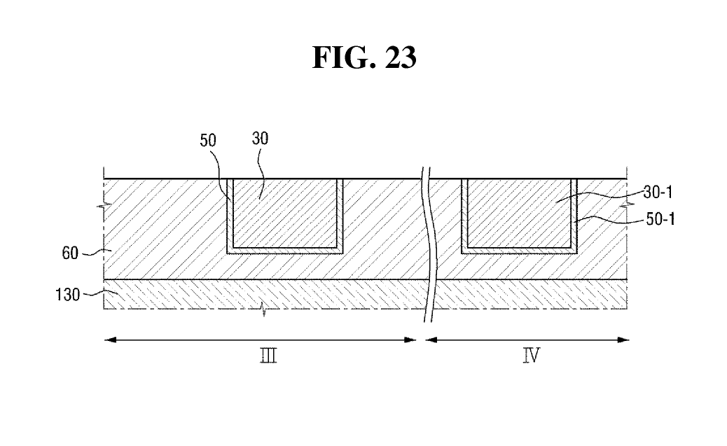

FIGS. 23 to 25 are views illustrating intermediate process steps for explaining a method for manufacturing the e-fuse device according to example embodiments of the present inventive concepts.

Referring first to FIG. 23, the first metal pattern 30 and the first barrier metal 50 are formed in the first interlayer insulation layer 60 on the third region III, and the second metal pattern 30-1 and the second barrier metal 50-1 are formed on the fourth region IV.

Here, the first electrode 10 and the second electrode 20 may be formed on the third region III at the same time or in advance. That is to say, an e-fuse structure may be formed on the third region III and a wiring structure may be formed on the fourth region IV.

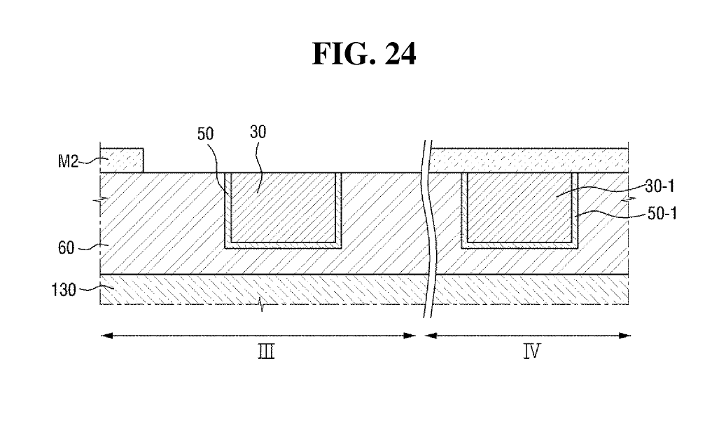

Next, referring to FIG. 24, a second mask M2 is formed in part of the third region III and in whole of the fourth region IV. The second mask M2 may be required to etch the first interlayer insulation layer 60 in the third region III. Therefore, in order to prevent the first interlayer insulation layer 60 in the fourth region IV from being etched, the second mask M2 may be formed in the fourth region IV such that the top surface of the first interlayer insulation layer 60 is completely covered by the second mask M2.

By contrast, in the third region III, in order to etch the first interlayer insulation layer 60 formed at opposite sides of the first metal pattern 30, the second mask M2 is only partially formed. Here, the first metal pattern 30 and the first barrier metal 50 may also be used as etch masks.

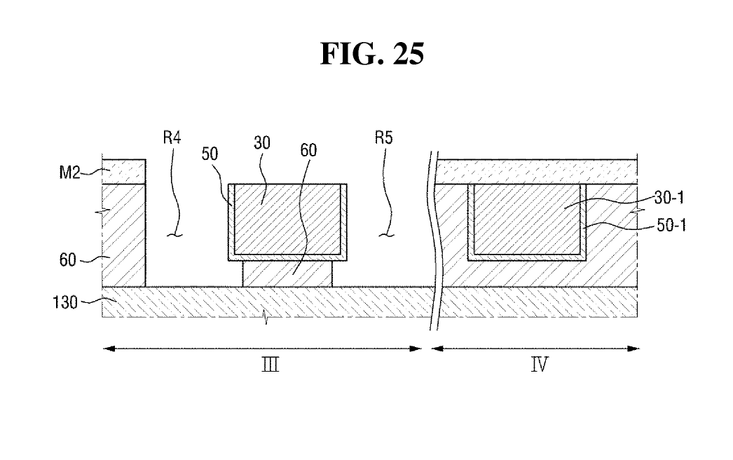

Next, referring to FIG. 25, in the third region III, a fourth recess R4 and a fifth recess R5 are formed on opposite lateral surfaces of the first metal pattern 30 and the first barrier metal 50. Here, the first interlayer insulation layer 60 and the second mask M2 may have etching selectivity with respect to each other. In addition, the first interlayer insulation layer 60, the first metal pattern 30 and the first barrier metal 50 may also have etching selectivity with respect to one another. Further, the first interlayer insulation layer 60 and the etch stop layer 130 may also have etching selectivity with respect to each other. That is to say, the second mask M2, the first metal pattern 30, the first barrier metal 50 and the etch stop layer 130, excluding the first interlayer insulation layer 60, may not etched or may be less etched.

Therefore, a bottom surface of the fourth recess R4 may correspond to the etch stop layer 130 or the first interlayer insulation layer 60 that is less etched. In addition, sidewalls of the fourth recess R4 may correspond to the first barrier metal 50 or the first interlayer insulation layer 60 that is less etched.

Likewise, a bottom surface of the fifth recess R5 may correspond to the etch stop layer 130 or the first interlayer insulation layer 60 that is less etched. In addition, sidewalls of the fifth recess R5 may correspond to the first barrier metal 50 or the first interlayer insulation layer 60 that is less etched.

The fourth recess R4 and the fifth recess R5 may be configured to extend in parallel with the first metal pattern 30.

Next, referring again to FIG. 22, the first capping insulation layer 40 is formed on the first metal pattern 30, the second metal pattern 30-1, the fourth recess R4 and the fifth recess R5, thereby forming the fourth air gap 120.

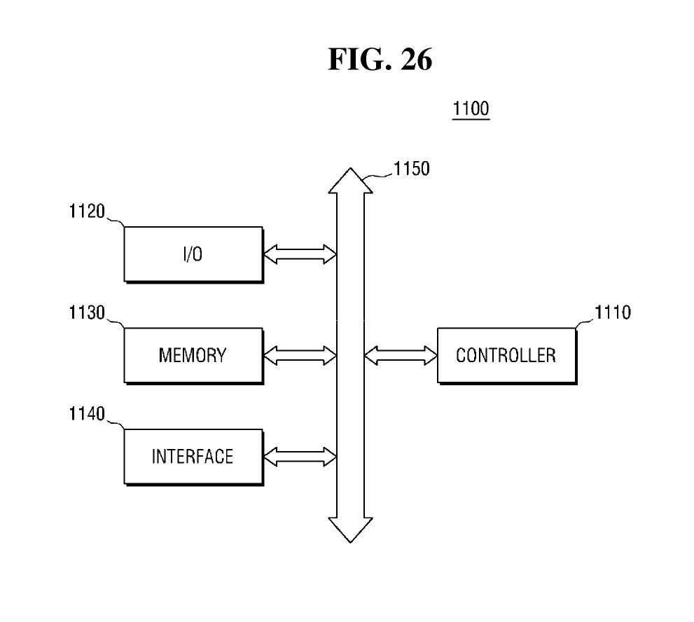

FIG. 26 is a block diagram illustrating an exemplary memory system including semiconductor devices according to example embodiments of the present inventive concepts.

Referring to FIG. 26, a memory system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

The memory system 1100 may include a controller 1110, an input/output device (I/O) 1120, such as a keypad, a keyboard, a display, and the like, a memory 1130, an interface 1140 and a bus 1150. The memory 1130 and the interface 1140 may be connected to each other through the bus 1150.

The controller 1110 may include at least one of a microprocessor, a digital signal processor, a microcontroller, and logic elements capable of functions similar to those of these elements. The memory 1130 may store commands executed by the controller 1110. The I/O 1120 may receive data or signals from the outside of the system 1100 or may output data or signals to the outside of the system 1100. The I/O 1120 may include, for example, a keypad, a keyboard, a display device, and so on.

The memory 1130 includes a nonvolatile memory device fabricated according to example embodiments of the present inventive concepts. The memory 1130 may further include other types of memories, volatile memories accessible at any time, and a variety of other types of memories.

The interface 1140 may perform functions of transmitting data to a communication network or receiving data from the communication network.

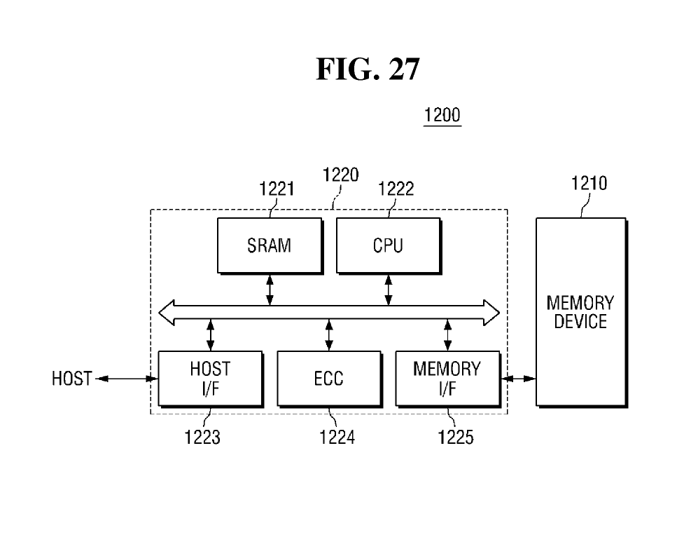

FIG. 27 is a block diagram illustrating an exemplary memory card including semiconductor devices according to example embodiments of the present inventive concepts.

Referring to FIG. 27, a memory card 1200 for supporting high-capacity data storage capability includes a multi-bit flash memory device 1210 according to example embodiments of the present inventive concepts. The memory card 1200 according to example embodiments of the present inventive concepts includes a memory controller 1220 controlling data exchange between a host and the multi-bit flash memory device 1210.

A static random access memory (SRAM) 1221 is used as a working memory of a processing unit 1222. A host interface 1223 includes a data exchange protocol of the host connected to the memory card 1200. An error correction block 1224 detects and corrects an error included in data read from the multi-bit flash memory device 1210. The memory interface 1225 interfaces with the flash memory device 1210 according to example embodiments of the present inventive concepts. The processing unit 1222 performs an overall controlling operation for data exchange of the memory controller 1220. Although not shown, it is obvious to one skilled in the art that the memory card 1200 according to example embodiments of the present inventive concepts may further include a read only memory (ROM) storing code data for interfacing with the host.

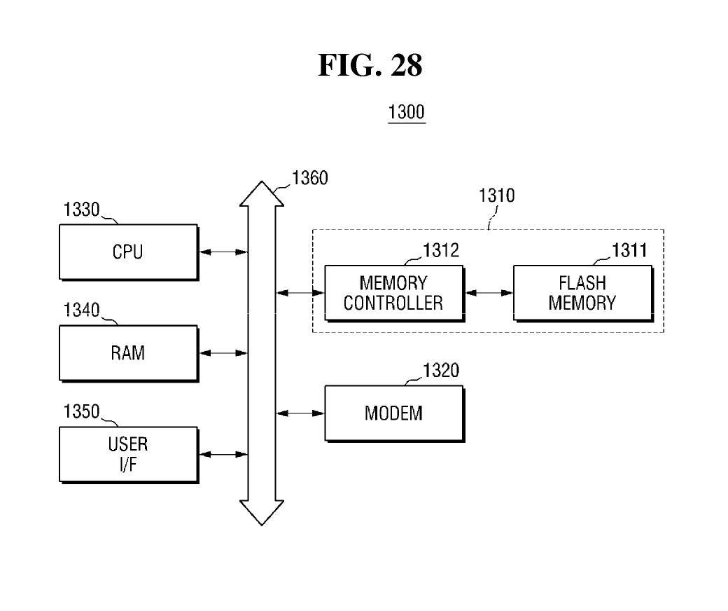

FIG. 28 is a block diagram illustrating an exemplary information processing system having a semiconductor device according to example embodiments of the present inventive concepts mounted therein.

Referring to FIG. 28, a memory system 1310 according to example embodiments of the present inventive concepts is built in an information processing system 1300 such as a mobile product or a desktop computer. The information processing system 1300 according to example embodiments of the present inventive concepts includes the memory system 1310 and a modem 1320, a central processing unit (CPU) 1330, a random access memory (RAM) 1340, and a user interface 1350 that are electrically connected to a system bus 1360, respectively. The memory system 1310 may be with the same as or substantially similar to the memory system or the memory system described above. The memory system 1310 stores data processed by the central processing unit 1330 or data received from an external device. Here, the memory system 1310 may comprise a solid state disk (SSD) and, in this case, the data processing system 1310 can stably store huge amounts of data in the memory system 1310. As reliability increases, the memory system 1310 can reduce resources used to correct errors, thereby providing a high speed data exchange function to the information processing system 1300. Although not illustrated in the drawing, it is apparent to one of ordinary skill in the art that the information processing unit 1300 in accordance with example embodiments of the present inventive concepts may further include an application chipset, a camera image processor (CIS) and/or an input/output device.

The foregoing is illustrative of example embodiments and is not to be construed as limiting thereof. Although a few example embodiments have been described, those skilled in the art will readily appreciate that many modifications are possible in example embodiments without materially departing from the novel teachings. Accordingly, all such modifications are intended to be included within the scope of the disclosure as defined in the claims. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. An e-fuse device, comprising:
a first metal pattern extending in a first direction to connect a first electrode and a second electrode to each other;
a first barrier metal contacting lateral surfaces and a bottom surface of the first metal pattern; and
a first capping insulation layer contacting a top surface of the first metal pattern,
the first metal pattern including an exposed region, the first barrier metal or the first capping insulation layer not contacting a top surface or a bottom surface of the exposed region.

2. The e-fuse device of claim 1, further comprising:
a first interlayer insulation layer on the first capping insulation layer,
the exposed region being on the top surface of the first metal pattern, and contacting the first interlayer insulation layer.

3. The e-fuse device of claim 2, wherein the first interlayer insulation layer includes a low-k dielectric.

4. The e-fuse device of claim 1, wherein
the exposed region is on the top surface of the first metal pattern, and
the first capping insulation layer and the exposed region define a cavity filled with air therebetween.

5. The e-fuse device of claim 4, wherein a top surface of the exposed region is lower than a top surface of the first metal pattern other than the exposed region.

6. The e-fuse device of claim 1, wherein
the exposed region is on the top surface of the first metal, and
the e-fuse device further comprises:
a first interlayer insulation layer on the first capping insulation layer; and
a second capping insulation layer on the interlayer insulation layer; and
the exposed region and the second capping insulation layer defining a cavity filled with air therebetween.

7. The e-fuse device of claim 6, wherein a top surface of the exposed region is equal to, or higher than a top surface of the first metal pattern other than the exposed region.

8. The e-fuse device of claim 6, wherein the first and second capping insulation layers are not in contact with each other.

9. The e-fuse device of claim 6, wherein sidewalls of the cavity include the second capping insulation layer and the first interlayer insulation layer.

10. The e-fuse device of claim 6, wherein
the first metal pattern and the air gap are formed in the first region, and
the e-fuse device further comprises:
a second metal pattern in the second region to be spaced apart from the first metal pattern and the first capping insulation layer; and
a via pattern extending through the first capping pattern and the first interlayer insulation layer, a top surface of the via pattern contacting the second capping insulation layer.

11. The e-fuse device of claim 10, wherein the via pattern includes a second barrier metal conformally along sidewalls and a bottom surface of the via pattern.

12. The e-fuse device of claim 1, wherein
the exposed region is on a bottom surface of the first metal pattern, and
the e-fuse device further comprises:
a second interlayer insulation layer contacting a bottom surface of the first barrier metal; and
a cavity filled with air between the second interlayer insulation layer and the first metal pattern.

13. An e-fuse device, comprising:
an interlayer insulation layer on a first etch stop layer;
a metal pattern filling a recess, the recess being in the interlayer insulation layer, and the metal pattern extending in a first direction; and
a capping insulation layer covering the metal pattern and the interlayer insulation layer,
lateral surfaces of the metal pattern and a bottom surface of the capping insulation layer defining a cavity filled with air, the cavity extending in the first direction, and
the cavity is not in contact the metal pattern.

14. The e-fuse device of claim 13, wherein the first etch stop layer and the interlayer insulation layer have an etching selectivity with respect to each other.

15. The e-fuse device of claim 13, further comprising:
a barrier metal covering an entirety of a bottom surface and lateral surfaces of the metal pattern in the first direction,
the cavity contacting the capping insulation layer, the interlayer insulation layer and the barrier metal.

16. An e-fuse device, comprising:
a metal pattern electrically connecting a first electrode and a second electrode;
a barrier metal under the metal pattern; and
a capping insulation layer over the barrier metal, the metal pattern having a region exposed by the capping insulation layer,
the metal pattern and at least one selected from the barrier metal and the capping insulation layer defining a cavity filled with air.

17. The e-fuse device of claim 16, wherein at least a surface of the metal pattern includes a material suitable for electromigration.

18. The e-fuse device of claim 16, further comprising:
an interlayer insulating layer over the capping insulation layer and contacting a top surface of the exposed region, the interlayer insulating layer including a material suitable for electromigration.

19. The e-fuse device of claim 16, wherein a bottom surface and lateral surfaces of the cavity are between the capping insulation layer and the metal pattern.

20. The e-fuse device of claim 16, wherein a bottom surface of the metal pattern and lateral surfaces of the barrier metal define lateral surfaces and a top surface of the cavity.
